(19) United States
(12) Patent Application Publication
(10) Pub. No.: US 2005/0030726 A1
(43) Pub. Date: Feb. 10, 2005

(54) Inverter power module for use in electric and electronic product

(75) Inventor: Cheol-jin Park, Suwon-city (KR)

Correspondence Address: SUGHRUE MION, PLLC, 2100 PENNSYLVANIA AVENUE, N.W., SUITE 800, WASHINGTON, DC, 20037, US

(73) Assignee: SAMSUNG ELECTRONICS CO., LTD.

(21) Appl. No.: 10/781,902

(22) Filed: Feb. 20, 2004

(30) Foreign Application Priority Data
Aug. 4, 2003 (KR) 2003-53717

(51) Int. Cl. H03K 3/42

(52) U.S. Cl. 361/792

(57) ABSTRACT

Disclosed is an inverter power module for use in the electric and electronic product, which includes: first elements constituting a power block; second elements constituting an inverter block; a mainboard on which the first elements are arranged; and a sub-board on which the second elements are arranged and mounted on the mainboard. On one portion in the front side of the main board, a sub-board mounting part for mounting the sub-board is provided. The sub-board mounting part has at least one connector and the sub-board has a pin header that corresponds to the connector. With these components, the sub-board is DIP-mounted on the mainboard. According to such construction, a plurality of the second elements having high probability of defect are included in the sub-board and mounted on the mainboard, whereby improvement in productivity and increase in yield are expected and defect generation can be minimized.

### CROSS-REFERENCE TO RELATED APPLICATIONS

This application claims the benefit of Korean Patent Application No. 2003-53717 filed Aug., 4 2003, in the Korean Intellectual Property Office, the disclosure of which is incorporated herein by reference.

### BACKGROUND

1. Field of the Invention

Apparatuses and methods consistent with the present invention relate to a power apparatus and method for use in an electric and electronic product, and more particularly, to an inverter power module of a one board type constituting a power apparatus of an LCD monitor, and a method for the same.

2. Description of the Related Art

According to the recent trend, a power apparatus for use in an electric and electronic product tends to have its power block and inverter block integrated on one board. A typical example of such inverter power module for use in the electric and electronic product is shown in FIG. 1A and FIG. 1B, which will be briefly described in the following.

As shown in FIG. 1A and FIG. 1B, the general inverter power module for use in the electric and electronic product consists of a plurality of parts constituting the power block and the inverter block arranged on the front side and the back side of a board 1, respectively.

On the board 1, a predetermined metal pattern for electrical connection of each element is formed. On the front side of the board 1, first elements such as an element 11 constituting an input rectifying block, a power-IC 12, a first switching FET 13, an element 14 constituting an output rectifying block, an element 15 constituting a feedback circuit block, a power transformer 16, and inverter transformers 17 and 17′, are installed. Also, on the back side of the board 1, second elements including a dimming element 21, an inverter-IC 22, a second switching FET 23, an element 24 constituting a feedback circuit block, and a protection element 25, are installed.

Here, the element 11 constituting the input rectifying block can be realized by a line filter, X-cap, Y-cap, for example, and the element 14 constituting the output rectifying block can be realized by a diode, an inductor and a capacitance. Also, the element 15 constituting the feedback circuit can be realized by a photocoupler. Generally, the first elements are dip-mounted (dual-in-line package-mounted) while the second elements are surface-mounted.

In the meantime, a driving circuit consisting of the second elements is controlled by an inverter controller, i.e., the inverter-IC 22, and given a DC from the power block, operating the second switching FET 23, whereby generating an AC in order to operate, for example, a lamp, most of which are designed to use a LC-resonance. Also, the dimming element 21 plays a role of adjusting the brightness of the lamp. Most of such driving circuits are realized by an active element such as FET, TR DIODE, IC, etc.

But, according to the inverter power module for use in the electric and electronic product as described above, a metal pattern of a complicated structure is formed to mount the second elements constituting the driving circuit on the back side of the single-layer board 1, and the second elements constituting the driving circuit should be surface-mounted on the back side of the board 1 after a plurality of the first elements are dip-mounted on the front side of the board 1, thus the circuits get complicated and many processes and much time are consumed for installation of the elements, whereby productivity drops.

Also, according to the conventional inverter power module for use in the electric and electronic product, a plurality of the elements are mounted in line with the wiring of the metal pattern on the front side and back side of the board 1, thus it is very difficult to realize the same property in an aspect of manufacturing process. Namely, the conventional inverter power module has a structure such that the reproducibility is deteriorated.

Also, according to the conventional inverter power module for use in the electric and electronic product, deterioration of yield levels and cost increases are unavoidable for the second elements constituting the driving circuit which have relatively high incidence of defect, are surface-mounted on the back side of the board 1, and thus, not only are defect levels high, it is difficult to repair only the relevant or defective element when there is a defect of the surface-mounted element in a test of an assembled product and it is necessary to throw away the whole board.

### SUMMARY

Accordingly, the present invention has been made to solve the problems mentioned above, and an aspect of the present invention is to provide an inverter power module for use in the electric and electronic product, capable of simplifying a metal pattern structure of a mainboard as well as achieving defect reduction and productivity improvement, by making a sub-board where a plurality of elements that have been mounted on the back side of the mainboard are included and by installing such sub-board on the mainboard.

Another aspect of the present invention is to provide an inverter power module for use in the electric and electronic product, which is capable of testing the sub-board only, before the sub-board is assembled on the mainboard and of reducing the generation of defect, by making the sub-board using elements having high possibility of defect.

In order to accomplish the above aspects and/or other features of the present invention, an inverter power module for use in the electric and electronic product includes: a plurality of first elements constituting a power block; a plurality of second elements constituting an inverter block; a mainboard on which the first elements are arranged; and a sub-board on which the second elements are arranged and mounted on the mainboard.

According to an exemplary embodiment of the present invention, a plurality of the first elements are mounted on the front side of the mainboard and a sub-board mounting part for mounting the sub-board is provided on one portion in the front side of the mainboard.

Here, the sub-board mounting part has at least one connector and the sub-board has a pin header that corresponds to the connector. By such members, the sub-board is through hole-mounted on the mainboard.

In the meantime, the first elements may also be surface-mounted on the mainboard.

Also, the second elements may be surface-mounted or through hole-mounted on the sub-board, and may be arranged on one side or both sides of the sub-board.

According to another exemplary embodiment of the present invention, the sub-board mounting part may be provided on one portion in the back side of the mainboard, and in that case, the sub-board is surface-mounted. Therefore, the sub-board mounting part has a metal pattern for electrical connection and the sub-board has a metal pad that corresponds to the metal pattern.

Also, in accordance with the present invention, an inverter power module for use in the electric and electronic product includes: a mainboard on which a plurality of first elements are through hole-mounted; a sub-board on which a plurality of second elements are surface-mounted, wherein a connector for mounting the sub-board in a through hole-mounting manner is provided on the side of the mainboard where the first elements are mounted and a pin header that corresponds to the connector is provided on the sub-board.

Also, in accordance with the present invention, an inverter power module for use in the electric and electronic product includes: a mainboard on which a plurality of first elements are through hole-mounted; a sub-board on which a plurality of second elements are surface-mounted, wherein a predetermined metal pattern for mounting the sub-board in a surface-mounting manner is formed on a back side in the side of the mainboard where the first elements are mounted and a pad that corresponds to the metal pattern is provided on the sub-board.

The first elements have a line filter, X-cap, Y-cap, a power-IC, a switching FET constituting an input rectifying block; a diode, an inductor, a capacitor constituting an output rectifying block; and a photocoupler, a power transformer, an inverter transformer constituting a feedback circuit block. Also, the second elements have a dimming element; an inverter-IC; a first and a second switching FETs; and a first and a second protection elements.

In addition, a method for effecting the above aspects of the present invention is disclosed.

### BRIEF DESCRIPTION OF THE DRAWINGS

The above objects and other advantages of the present invention will be more apparent from the following detailed description when taken in conjunction with the accompanying drawings, in which:

FIG. 1A and FIG. 1B are a plan view and a back side view, respectively, showing exemplary element arrangements of the conventional inverter power module for use in the electric and electronic product;

FIG. 2 is a partial, exploded, perspective view showing an exemplary element arrangement of an inverter power module for use in the electric and electronic product according to one embodiment of the present invention;

FIG. 3 is a plan view showing an exemplary element arrangement of a sub-board that is a part of the inverter power module shown in FIG. 2; and

FIG. 4A and FIG. 4B are a plan view and a back side view, respectively, showing exemplary arrangements of an inverter power module for use in the electric and electronic product according to another embodiment of the present invention.

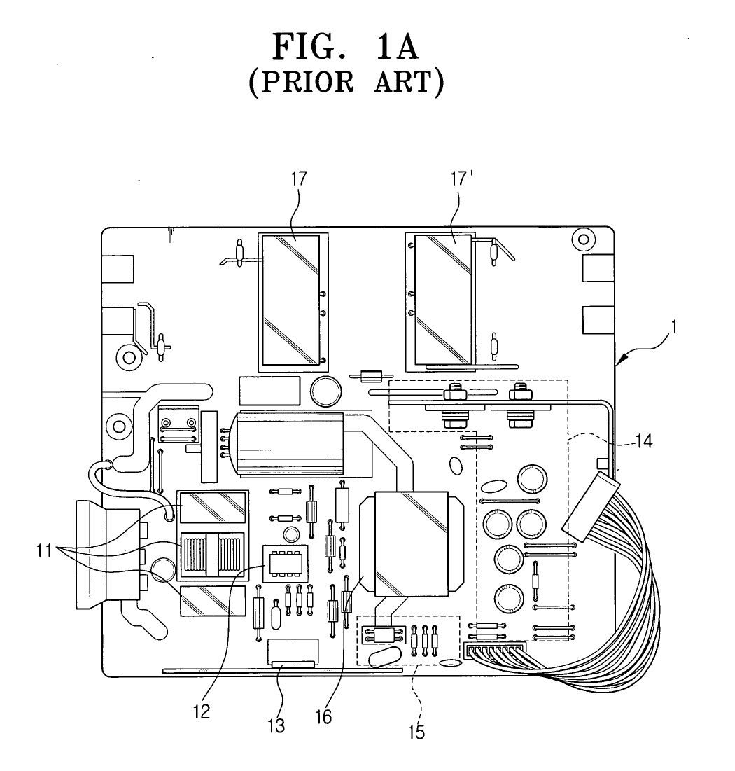

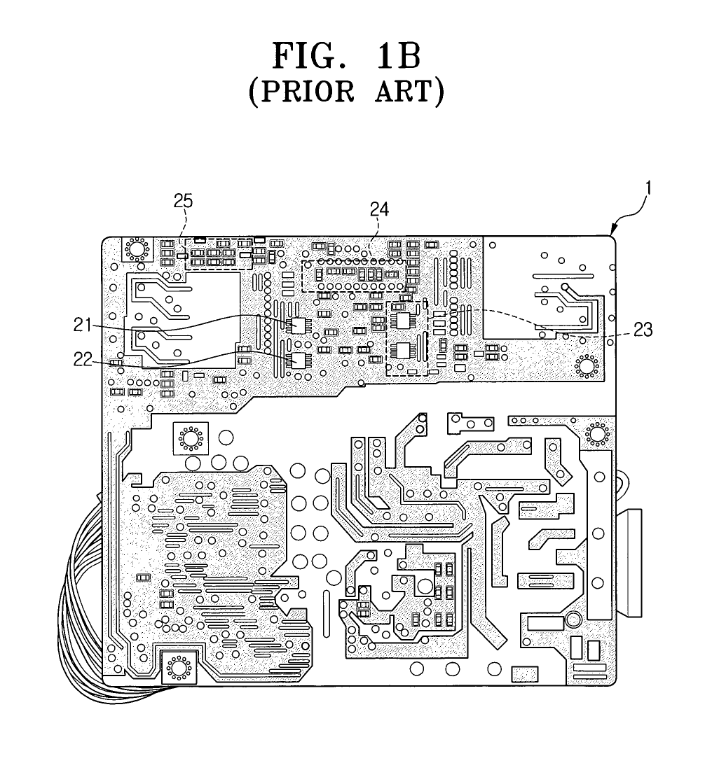

### DETAILED DESCRIPTION OF EXEMPLARY EMBODIMENTS

An exemplary embodiment of the present invention will now be described with reference to the accompanying drawings.

In the following description, same drawing reference numerals are used for the same elements even in different drawings. The matters defined in the description such as a detailed construction and elements are nothing but the ones provided to assist a comprehensive understanding of the invention. Thus, it is apparent that the present invention can be carried out without those defined matters. Also, well-known functions or constructions are not described in detail since they would obscure the invention in unnecessary detail.

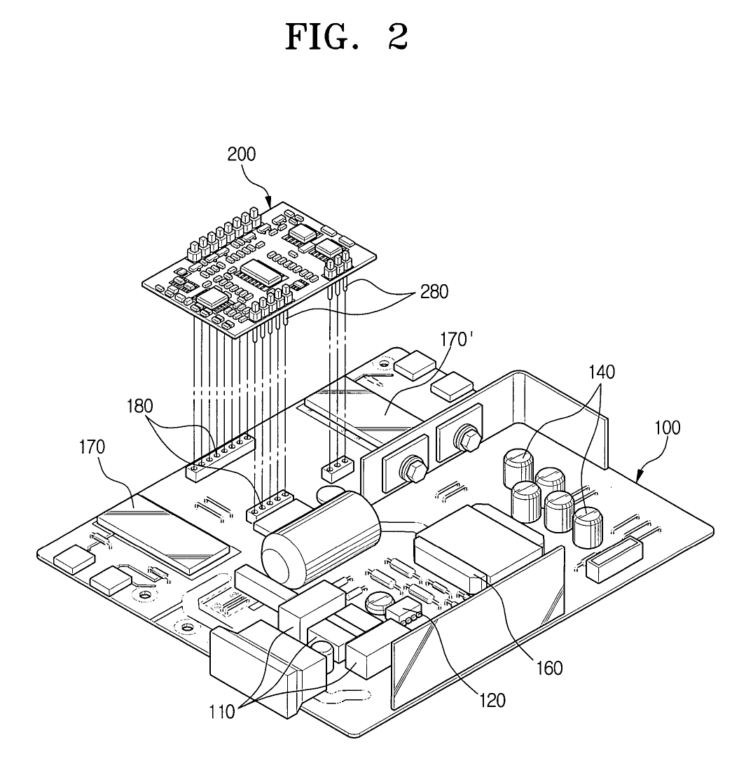

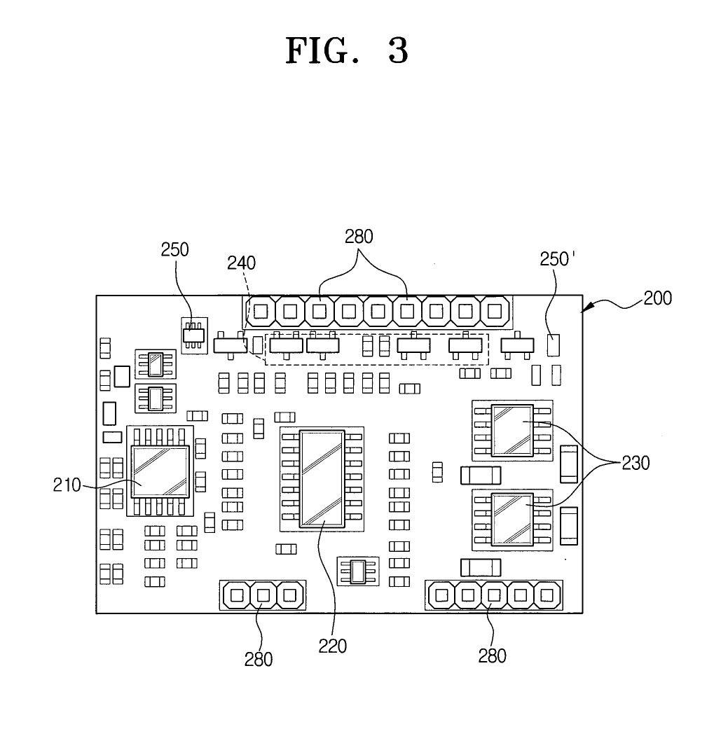

As shown in FIG. 2 and FIG. 3, an inverter power module for use in the electric and electronic product according to one embodiment of the present invention, has a mainboard 100 and a sub-board 200, which construct a dual-part structure. The sub-board 200 is mounted on the mainboard 100 in a simple manner, such as through hole-mounting including dual-in-line package mounting (dip-mounting), pin grid array mounting, single-in-line mounting, and zig-zag-in-line mounting, or surface mounting.

On the mainboard 100 and the sub-board 200, a predetermined metal pattern for electrical connection of each mounted element, is formed.

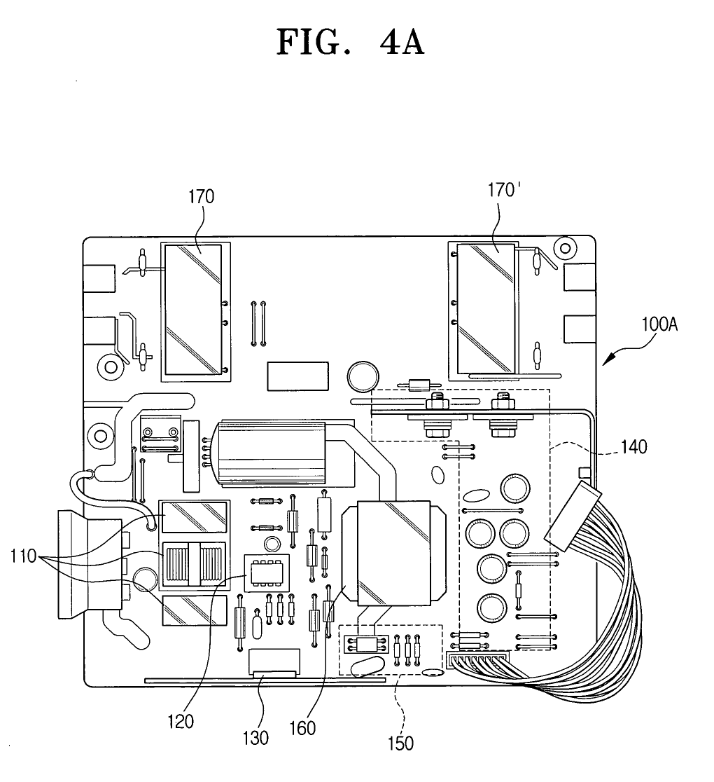

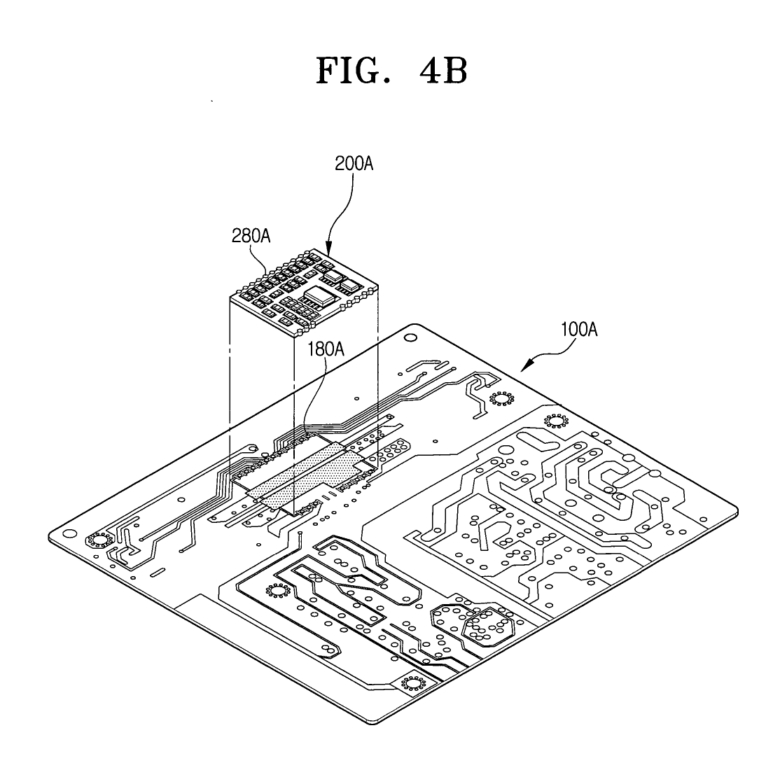

On the mainboard 100, the first elements constituting the power block such as an element 110 constituting an input rectifying block, a power-IC 120, the first switching FET 130 (refer to FIG. 4A), an element 140 constituting an output rectifying block, an element 150 constituting a feedback circuit block (refer to FIG. 4A), a power transformer 160, and inverter transformers 170, 170=40 are mounted. These elements are preferably, but not necessarily, through hole-mounted, e.g., dip-mounted, or may be surface-mounted.

Also, according to one embodiment of the present invention, on the front side of the mainboard 100, e.g., on one portion of the side where the elements are mounted, more specifically, between the inverter transformers 170 and 170′, a connector 180 as a sub-board mounting part for mounting the sub-board 200 that will be described below, on the mainboard 100, is installed. Although not specifically shown, the connector 180 is mounted in the mainboard 100 with its lead connected with the metal pattern of the mainboard 100.

On the sub-board 200, the second elements constituting the inverter block, such as a dimming element 210, an inverter-IC 220, the second switching FET 230, an element 240 constituting a feedback circuit block, protection elements 250 and 250′ that have been surface-mounted on the back side of the mainboard in the conventional inverter power module, are mounted. These elements may be surface-mounted on one side of the sub-board 200 in a concentrated manner, or may be divided into two parts and mounted on both sides of the sub-board 200. In the latter case, it is preferable, but not necessary, that the element for one side is through hole-mounted, e.g., dip-mounted, and the element for the other side is surface-mounted.

Also, the sub-board 200 has a pin header 280 that corresponds to the connector 180 and mounts the sub-board 200 on the sub-board mounting part of the mainboard 100 in a detachable manner. Although the sub-board 200 is mounted on the mainboard 100 in a detachable manner by means of the connector 180 and the pin header 280 in the exemplary view, the sub-board 200 may also be through hole-mounted, e.g., dip-mounted, directly on the mainboard 100. But, upon defect generation at the sub-board 200, the former case of using connector 180 and pin header 280 has a benefit of easily replacing only the sub-board, while the latter case, upon defect generation at the sub-board 200, has a weak point in that it is difficult to replace the sub-board 200 and the whole mainboard should be thrown away depending on the situation. Therefore, the former case is preferable.

In the embodiment of the present invention, for the element 110 constituting the input rectifying block, a line filter, X-cap, Y-cap are used, for example, and for the element 140 constituting the output rectifying block, a diode, an inductor, a capacitor are used, and for the element 150 constituting the feedback circuit block, a photocoupler is used.

The inverter power module for use in the electric and electronic product according to one embodiment of the present invention, is manufactured very easily, through the following process.

First, the first elements are mounted on the mainboard 100, and the second elements are mounted on the sub-board 200. As mounting these elements is performed by a known process, detailed description thereof will be omitted. The only difference is that the connector 180 is mounted together on the mainboard 100 upon through hole-mounting, e.g., dip-mounting, of the first elements and the pin header 280 is mounted together on the sub-board 200 upon mounting of the second elements.

Next, the pin header 280 of the sub-board 200 is fit in the connector 180 of the mainboard 100 so that the sub-board 200 is assembled to the mainboard 100.

As described, unlike the conventional inverter power module where the first elements are dip-mounted on the front side of the one single board and the second elements are surface-mounted on the back side of the one single board, the present invention has such construction that the board is divided into two parts, i.e., the mainboard 100 and the sub-board 200, then the first elements are mounted on the mainboard 100 and the second elements having a high probability of defects are mounted on the sub-board 200 so that these two boards are simply assembled, thus defect generation could be remarkably reduced and productivity could be improved when compared to the conventional inverter power module.

FIG. 4A and FIG. 4B show the inverter power module for use in the electric and electronic product according to another embodiment of the present invention. As revealed in the drawings, the inverter power module for use in the electric and electronic product according to another embodiment of the present invention is not much different from the first embodiment described above. One difference is a mounting structure of the sub-board 200A with respect to the mainboard 100A.

Namely, according to the another embodiment of the present invention, a predetermined metal pattern 180A for use as a sub-board mounting part is formed on the back side of the mainboard 100A, and a metal pad 280A for connecting with the predetermined metal pattern 180A is formed on the sub-board 200A so that the sub-board 200A is surface-mounted on the mainboard 100A, as shown in FIG. 4B.

As other constructions and effects constituting the inverter power module for use in the electric and electronic product are the same or similar as the first embodiment described above, detailed description thereof will be omitted.

As is apparent from the foregoing, the inverter power module is assembled through the simple process of mounting the elements on one side of the board that is divided into two parts, thus productivity and reproducibility can be enhanced.

Also, according to the present invention, the elements are not mounted on both sides of the board, and particularly, the elements having high probability of defects are mainly mounted on the sub-board, then the sub-board is simply assembled on the mainboard, thus the circuit construction of the board could be simplified and degree of freedom in parts arrangement for the elements is increased, which are strong points in an aspect of product design.

Also, according to the present invention, the elements having high probability of defect are mounted on the sub-board and separately managed apart from the mainboard so that a test for the sub-board only becomes possible and judgment as to whether the sub-board is defective or not is also possible regardless of the mainboard. Also, upon defect generation of the sub-board, it is possible to separate the sub-board from the mainboard for repairing the sub-board only. Namely, according to the present invention, improvements in yield and cost reduction are achieved.

While the invention has been shown and described with reference to certain exemplary embodiments thereof, it will be understood by those skilled in the art that various changes in form and details may be made therein without departing from the spirit and scope of the invention as defined by the appended claims. Therefore, all such proper modifications, changes and equivalents of the embodiments of the present invention will fall within the scope of the invention.

1. An inverter power module for use in an electric and electronic product, comprising:
a power block;
an inverter block;
a mainboard on which the power block is arranged; and
a sub-board on which the inverter block is arranged, wherein the sub-board is mounted on the mainboard.

2. The module according to claim 1, wherein the power block comprises a plurality of first elements through hole-mounted on a front side of the mainboard and a sub-board mounting part for mounting the sub-board is provided on one portion on a front side of the main board.

3. The module according to claim 2, wherein the sub-board mounting part comprises at least one connector and the sub-board comprises a pin header corresponding to the connector.

4. The module according to claim 3, wherein the inverter block comprises second elements surface-mounted on one side of the sub-board.

5. The module according to claim 3, wherein the inverter block comprises second elements mounted on front and back sides of the sub-board.

6. The module according to claim 1, wherein the power block comprises a plurality of first elements through hole-mounted on a front side of the mainboard and a sub-board mounting part for mounting the sub-board is prepared on one portion on a back side of the main board.

7. The module according to claim 6, wherein the sub-board mounting part has a predetermined metal pattern and the sub-board has a pad corresponding to the metal pattern.

8. The module according to claim 7, wherein the inverter block comprises second elements surface-mounted on one side of the sub-board.

9. The module according to claim 7, wherein the inverter block comprises second elements mounted on front and back sides of the sub-board.

10. An inverter power module for use in an electric and electronic product, comprising:
a mainboard on which a plurality of first elements are through hole-mounted;
a sub-board on which a plurality of second elements are surface-mounted,
wherein a connector for mounting the sub-board in a through hole-mounting manner is provided on a side of the mainboard where the first elements are mounted, and a pin header corresponding to the connector is provided on the sub-board.

11. The module according to claim 10, wherein the first elements comprise a line filter; X-cap; Y-cap; a power-IC; an input rectifying block comprising a first switching FET; an output rectifying block comprising a diode, an inductor, and a capacitor; and a feedback circuit block comprising a photocoupler, a power transformer, and an inverter transformer, and
the second elements comprise a dimming element; an inverter-IC; a second switching FET; a third switching FET; a first protection element; and a second protection element.

12. An inverter power module for use in an electric and electronic product, comprising:
a mainboard on which a plurality of first elements are through hole-mounted; and
a sub-board on which a plurality of second elements are surface-mounted,
wherein a predetermined metal pattern for mounting the sub-board in a surface-mounting manner is formed on a back side of the mainboard where the first elements are mounted and a pad corresponding to the metal pattern is provided on the sub-board.

13. The module according to claim 12, wherein the first elements comprise a line filter; X-cap; Y-cap; a power-IC; an input rectifying block comprising a first switching FET; an output rectifying block comprising a diode, an inductor, and a capacitor; and a feedback circuit block comprising a photocoupler, a power transformer, and an inverter transformer, and
the second elements comprise a dimming element; an inverter-IC; a second switching FET; a third switching FETs; a first protection element; and a second protection element.

14. The module according to claim 2, wherein the plurality of first elements are dual-in-line package-mounted on the front side of the mainboard.

15. The module according to claim 6, wherein the plurality of first elements are dual-in-line package-mounted on the back side of the mainboard.

16. An inverter power module for use in an electric and electronic product, comprising:
a power block;
an inverter block;
a mainboard on which the power block is arranged;
a sub-board on which the inverter block is arranged; and
means for releasably mounting the sub-board on the mainboard.

17. The module according to claim 16, wherein the power block comprises a line filter; X-cap; Y-cap; a power-IC; an input rectifying block comprising a first switching FET; an output rectifying block comprising a diode, an inductor, and a capacitor; and a feedback circuit block comprising a photocoupler, a power transformer, and an inverter transformer, and
the second elements comprise a dimming element, an inverter-IC, a second switching FET, a third switching FET, a first protection element, and a second protection element.

18. The module according to claim 16, wherein the means for releasably mounting the sub-board on the mainboard comprises one of a first mounting member and a second mounting member, wherein the second mounting member is complementary to the first mounting member, disposed on the sub-board, and another of the first mounting member and the second mounting member disposed on the mainboard.

19. A method for assembling an inverter power module, said method comprising:
substantially aligning a first mounting member disposed on a sub-board comprising an inverter block, with a second mounting member disposed on a mainboard comprising a power block;
releasably joining the first mounting member with the second mounting member.

20. The method as recited in claim 19, wherein the releasably joining comprises fastening the first mounting member to the second mounting member.

21. The method as recited in claim 20, wherein fastening the first mounting member to the second mounting member comprises through hole-mounting.
